(19) United States
(12) Patent Application Publication
(10) Pub. No.: US 2020/0036162 A1
(43) Pub. Date: Jan. 30, 2020

(54) LASER

(71) Applicant: HUAWEI TECHNOLOGIES CO., LTD., Shenzhen (CN)

(72) Inventor: Xin CHEN, Ipswich (GB)

(21) Appl. No.: 16/594,518

(22) Filed: Oct. 7, 2019

Related U.S. Application Data
(63) Continuation of application No. PCT/EP2017/058416, filed on Apr. 7, 2017.

(51) Int. Cl. H01S 5/12; H01S 5/10; H01S 5/065; H01S 5/028; H01S 5/022; H01S 5/30

(52) U.S. Cl. CPC H01S 5/1203; H01S 5/1039; H01S 5/0653; H01S 5/02284; H01S 5/02288; H01S 5/3013; H01S 5/0287

(57) ABSTRACT

An example laser has a rear reflector, a front facet spaced from the rear reflector, and a laser cavity defined between the rear reflector and the front facet. The laser comprises a Bragg grating located in the laser cavity, where a length of the Bragg grating (L_{g}) is in a range from 40% to 60% of a distance from the rear reflector to front of the Bragg grating, and a grating strength (Kappa*L_{g}) is in a range from 0.6 to 1.5.

### CROSS-REFERENCE TO RELATED APPLICATIONS

This application is a continuation of International Application No. PCT/EP2017/058416, filed on Apr. 7, 2017, the disclosure of which is hereby incorporated by reference in its entirety.

### BACKGROUND

This invention relates to lasers, for example to improving the yield and reflection tolerance of distributed feedback lasers.

High-performance and low-cost laser modules are used in applications such as large-capacity and high-speed optical access networks.

A conventional laser diode generally comprises a semiconductor block which has a front face or facet, a rear face or facet opposite to the front facet and a laser cavity formed therebetween. The cavity traditionally comprises an active layer interposed between layers of p- or n-type semiconductor material. One or more coating layer(s), such as anti-reflection (AR) or high reflection (HR) coatings, may be applied to the front and the rear facets to provide a predetermined reflectivity.

In distributed feedback (DFB) lasers, a Bragg grating acts as the wavelength selective element for at least one of the faces and provides feedback, reflecting light back into the cavity to form the resonator. The grating is constructed so as to reflect only a narrow band of wavelengths. Thus, DFB lasers typically function at a single longitudinal lasing mode.

Traditionally, DFB lasers are AR coated on one side of the cavity and HR coated at the other side. The side with the AR coating is the front of the laser, through which light is to be emitted. The side with the HR coating is the back of the laser. The grating may act as a distributed mirror inboard of the AR coated side of the cavity. The HR coating acts as a mirror on the other side of the cavity. The HR coated side inhibits losses from the rear of the cavity.

This mode of operation is in contrast to a Fabry-Perot (FP) laser, where the cavity consists of two opposing reflective surfaces. The front and rear facets, which may be coated, form the two reflective faces and provide the feedback. For the case of a FP laser, the laser may either function at multiple longitudinal modes simultaneously or easily jump between longitudinal modes.

The front and/or rear face(s) of a laser may be formed by cleaving. Cleaving is a mechanical operation, and it is difficult to control with the utmost precision. During the manufacture of a laser, it is very difficult to control precisely where the material cleaves to form a facet. In a typical DFB laser, the location of the facets affects the phase of the reflected waveform. If the position of a facet is uncertain then the precise length of the laser cavity is unknown. This affects the optical mode profile along the lasing cavity and the output spectrum of the laser.

Standard DFB lasers suffer yield loss as a result of the random phase of the waves reflected from the facets. This can also result in optical mode hop, a decrease in the optical power output and the front/back output power ratio can spread greatly between approximately 8 to 40.

Additionally, laser performance can be sensitive to external optical reflections. The standard way to solve this problem is to position an isolator in front of a DFB laser. However, if the reflection is from a coupling lens, for example connecting the laser to an optical fibre, it is very difficult to solve this problem. Additionally, the optical isolators usually inserted in DFB laser modules to reduce the optical reflection make the laser modules more expensive and larger than desired.

It is desirable to develop a laser where the facet phase random change does not have a great impact on the optical mode profile along the laser cavity, such that the laser will have a higher yield and is insensitive to external optical reflection.

### SUMMARY OF THE INVENTION

According to one aspect there is provided a laser having a rear reflector, a front facet spaced from the rear reflector and a laser cavity defined between the rear reflector and the front facet, the laser comprising a Bragg grating located in the cavity, wherein the length of the Bragg grating (L_{g}) is in the range from 40% to 60% of the distance from the rear reflector to the front of the grating and the grating strength (Kappa*L_{g}) is in the range from 0.6 to 1.5.

The rear reflector may be a back facet. The back facet may be coated with a high reflection coating. This may improve the performance of the laser.

Modelling has shown that for a laser with the above characteristics, the random facet location relative to the grating phase as a result of the cleaving process does not have a great impact on the optical mode profile along the laser cavity. Hence, the laser can have a very stable and low front facet and back facet output ratio, and can be expected to have a better yield than conventional DFB lasers, and to be more insensitive to external optical reflection.

The laser may be a distributed feedback laser. This may be a convenient operational format.

The Bragg grating may be elongated along the length of the cavity. The elongation of the length may be orthogonal to the rear reflector. This allows the grating to be disposed between the semiconductor layers of the laser cavity.

The length of the Bragg grating (L_{g}) may be in the range from 45% to 55% of the distance from the rear reflector to the front of the grating. A value within this smaller range results in better performance compared to the broader range described above.

The grating strength may be in the range from 0.8 to 1.3. A grating strength value within this smaller range results in better performance compared to the broader range described above.

The laser may be configured so that in operation it functions in Fabry-Perot mode. This may allow the laser to function at multiple longitudinal modes simultaneously or easily jump between longitudinal modes.

The laser may be configured such that if the material defining the cavity is cut to form a new front facet not more than 100 nm closer to the rear reflector than the said front facet, the new front facet having the same reflectivity as the said front facet, the laser would, in operation, function in Fabry-Perot mode. This may result in the laser being insensitive to the inaccuracies of the position of the front facet as a result of the cleaving process.

The front facet may be a cleaved facet. This is a convenient method for manufacturing the laser.

The front face may be coated with an anti-reflection coating. This may improve the performance of the laser.

The front facet of the laser may be optically coupled to a lens. This may allow the laser to be coupled to an optical fibre.

The rear reflector may be planar and the said distance from the rear reflector to the front of the grating is measured in a direction perpendicular to the rear reflector.

The laser cavity may comprise a first semiconductor layer of a first doping type, a second semiconductor layer of a second doping type opposite to the first type, and an active region located between the first and second semiconductor layers, the first and second semiconductor layers being elongated in a direction extending between the rear reflector and the front face. This is a convenient laser configuration.

The Bragg grating may be located between the first and second semiconductor layers.

The laser cavity may comprise an amplifier. The laser cavity may comprise a modulator. This may allow the laser to be integrated with other optically functional structures.

### BRIEF DESCRIPTION OF THE FIGURES

The present invention will now be described by way of example with reference to the accompanying drawings.

In the drawings:

FIG. 1 shows a laser with a Bragg grating positioned adjacent to the front facet of the laser cavity.

FIG. 2 illustrates a laser with a Bragg grating spaced from the front facet of the laser cavity.

FIG. 3 illustrates a laser coupled to an optical fibre.

### DETAILED DESCRIPTION OF THE INVENTION

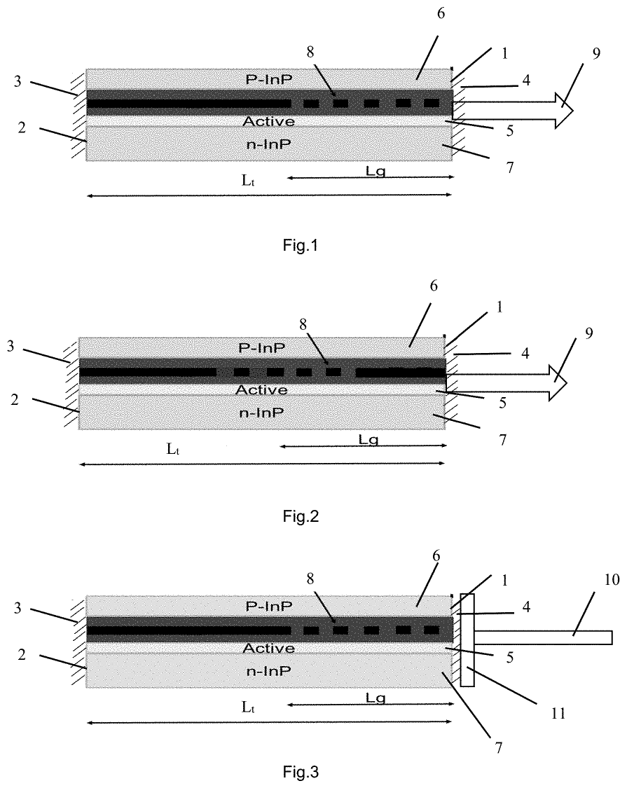

As illustrated in FIG. 1, one form of laser comprises a semiconductor block which has a front face or facet 1, a rear face or facet 2 opposite to the front face or facet and a laser cavity formed therebetween. The total length of the laser cavity is Lt. A high reflection (HR) coating 3 is applied to the rear facet and an anti-reflection (AR) coating 4 is applied to the front facet. The back facet with the HR coating acts as a rear reflector.

In the example shown in FIG. 1, the laser cavity comprises an active layer 5 interposed between layers of p- and n-type semiconductor material, shown at 6 and 7 respectively. A Bragg grating 8 is positioned adjacent to the front facet between the active layer 5 and the p-type semiconductor layer 6. The grating may alternatively be positioned between the active layer and the n-type semiconductor layer 7. The Bragg grating is integral with the cavity of the laser. The Bragg grating has a length L_{g}. The Bragg grating is elongated along the length of the cavity. The elongation of length of the grating is orthogonal to the rear facet. Light exits the laser cavity at the front facet, shown at 9.

It is preferable that the front and rear facets are aligned parallel to one another. Preferably the rear facet is orthogonal to the length of the cavity and/or to the Bragg grating. Preferably the front facet is orthogonal to the length of the cavity and/or to the Bragg grating.

In this example, the semiconductor layers are made from InP. However, other semiconductor materials, such as GaAs, may be used. The material forming the cavity may be selectively doped in the region of the p- and n-type layers 6, 7. The Bragg grating 8 may be positioned between different semiconductor layers to those shown in the example of FIG. 1.

For the laser of FIG. 1, the length of the grating (L_{g}), shown at 8, is between 40% to 60% of the total laser cavity length, Lₜ. Preferably, L_{g} is in the range from 45% to 55% of the total laser cavity length, Lₜ. The grating coupling strength, K*L_{g}, (where K represents the coupling coefficient, kappa) is between 0.7 and 1.4. Preferably, K*L_{g} is between 0.8 and 1.3. Values of L_{g} and grating strength within these narrower ranges can be expected to result in better performance compared to the broader ranges specified above.

This configuration results in a laser that is a hybrid between a Distributed Feedback (DFB) laser and a Fabry Perot (FP) laser.

Modelling has shown that for a laser with the above characteristics, the random facet location relative to the grating phase as a result of the cleaving process does not have a great impact on the optical mode profile along the laser cavity. Hence, the laser can be expected to have a better yield than conventional DFB lasers, and to be more insensitive to external optical reflection.

For such a laser, the single mode laser wavelength is selected from the FP modes by the partial grating in the section of the laser cavity between the rear HR facet and the grating. The FP mode is formed by the grating also acting as a reflector together with the HR coated rear facet. Optionally there may be a second grating located at or near the rear facet which may contribute to the laser operating in FP mode.

For such a laser, the lasing mode profile along the cavity and the yield of the laser is not affected by the random phase of the cleaved facets. Additionally, the front/back output power ratio remains consistent, with a low spread of around 6 to 15, in comparison with standard DFB lasers.

The laser configuration described above also reduces the spatial hole burning effect, which can also cause low yield. Where cleaved facets result in a random phase of the reflected waveforms, there will be an uneven distribution of optical modes along the cavity. This can result in uneven depletion of charge carriers. At some positions, there will be a strong optical mode inside the cavity and charge carriers are depleted quickly. At other positions, there will be a higher density of charge carriers where the mode is weaker. By using a laser with the configuration as described above, the mode is more evenly distributed along the cavity.

As described above, preferably the front facet is coated in an AR coating. By using an AR coating on the front face, the value of K*L_{g} can be between 0.7 and 1.4. If the facet is more reflective, K*L_{g} is preferred to be closer to 1 in order to operate in FP mode.

The laser is configured to operate in Fabry Perot mode regardless of any small variations in the position of the front face as a result of the cleaving process. The position of the front face may vary by 100 nm, 50 nm, or 20 nm as a result of the cleaving process. The optical mode profile along the cavity is not affected by the random phase of the front face as a result of the cleaving process.

Instead of the front grating being positioned adjacent to the front face of the laser cavity, the grating may be spaced from the front face, towards the rear face, as shown in FIG. 2. The grating may be spaced from the front face by greater than the pitch of the grating, or more than 2, 3, 4 or more times the pitch of the grating. In this example, the front section of the cavity between the grating and the front face can act as an optical amplifier. The length of the grating L_{g} is between 40% to 60% of the total laser cavity length, Lₜ. The grating coupling strength, K*L_{g}, is between 0.7 and 1.4.

As shown in FIG. 3, the laser may be coupled to an optical fibre 10 by a coupling lens 11.

The Bragg grating may be fabricated by electron beam lithography. This allows the accuracy of the grating spacing to be controlled very accurately. The pitch of the grating may be approximately 300 nm, 200 nm, or 50 nm.

The grating may be an index coupled grating, a gain coupled grating or a complex coupled grating. The layer comprising the grating may be fabricated from a p-doped or n-doped semiconductor material.

The laser structure may be integrated with another optically functional structure, for example an electroabsorption modulator, a Mach-Zehnder modulator, or an amplifier.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. A laser having a rear reflector, a front facet spaced from the rear reflector and a laser cavity defined between the rear reflector and the front facet, the laser comprising a Bragg grating located in the laser cavity, wherein a length of the Bragg grating (L_{g}) is in a range from 40% to 60% of a distance from the rear reflector to front of the Bragg grating and wherein a grating strength (Kappa*L_{g}) is in a range from 0.6 to 1.5.

2. The laser of claim 1, wherein the laser is a distributed feedback laser.

3. The laser of claim 1, wherein the Bragg grating is elongated along a length of the laser cavity.

4. The laser of claim 1, wherein the length of the Bragg grating (L_{g}) is in a range from 45% to 55% of the distance from the rear reflector to the front of the Bragg grating.

5. The laser of claim 1, wherein the grating strength is in a range from 0.8 to 1.3.

6. The laser of claim 1, wherein the laser is configured to function, in operation, in Fabry-Perot mode.

7. The laser of claim 6, wherein the laser is configured such that if material defining the laser cavity is cut to form a new front facet not more than 100 nm closer to the rear reflector than the said front facet, the new front facet having a same reflectivity as the said front facet, the laser, in operation, functions in the Fabry-Perot mode.

8. The laser of claim 1, wherein the front facet is a cleaved facet.

9. The laser of claim 1, wherein the front facet is coated with an anti-reflection coating.

10. The laser of claim 1, wherein the front facet of the laser is optically coupled to a lens.

11. The laser of claim 1, wherein the rear reflector is planar, and wherein the said distance from the rear reflector to the front of the Bragg grating is measured in a direction perpendicular to the rear reflector.

12. The laser of claim 1, wherein the laser cavity comprises a first semiconductor layer of a first doping type, a second semiconductor layer of a second doping type opposite to the first doping type, and an active region located between the first and second semiconductor layers, the first and second semiconductor layers being elongated in a direction extending between the rear reflector and the front facet.

13. The laser of claim 12, wherein the Bragg grating is located between the first and second semiconductor layers.

14. The laser of claim 1, wherein the laser cavity comprises an amplifier.

15. The laser of claim 1, wherein the laser cavity comprises a modulator.
